(19) United States
(12) Patent Application Publication
(10) Pub. No.: US 2026/0083006 A1
(43) Pub. Date: Mar. 19, 2026

(54) MEMORY MODULE INCLUDING PROTECTIVE LAYER

(71) Applicant: SAMSUNG ELECTRONICS CO., LTD., SUWON-SI (KR)

(72) Inventors: Jungkyu Kim, Suwon-si (KR); Sanghwan Kim, Suwon-si (KR); Hyuna Lee, Suwon-si (KR); Dongmin Jang, Suwon-si (KR); Jaeseok Jang, Suwon-si (KR)

(21) Appl. No.: 19/175,055

(22) Filed: Apr. 10, 2025

(30) Foreign Application Priority Data
Sep. 13, 2024 (KR) 10-2024-0125328

(51) Int. Cl. H01L 25/065; H10B 80/00

(52) U.S. Cl. CPC H10W 90/00; H10B 80/00; H10W 90/721; H10W 90/722

(57) ABSTRACT

A memory device including a module substrate having a first side surface and a second side surface perpendicular to the first side surface, a semiconductor package disposed on at least one of an upper surface and a lower surface of the module substrate, a passive device disposed on at least one of the upper surface and the lower surface of the module substrate, wherein the passive device is electrically connected to the semiconductor package, and a protective layer disposed on and covering the passive device. The module substrate includes a connector adjacent to the first side surface, the passive device includes a first passive device disposed between the connector and the semiconductor package, and the protective layer includes a first protective layer covering at least a portion of the first passive device.

### CROSS-REFERENCE TO RELATED APPLICATION(S)

This U.S. non-provisional patent application claims priority under 35 U.S.C. § 119 to Korean Patent Application No. 10-2024-0125328 filed on Sep. 13, 2024 in the Korean Intellectual Property Office, the disclosure of which is incorporated by reference herein in its entirety.

### BACKGROUND

Embodiments of the present disclosure relate to a memory module including a protective layer.

In a data processing system such as a personal computer (PC), a server computer or the like, a memory module may be used as a data storage device. For example, the memory module may include a plurality of semiconductor packages (for example, memory packages) mounted on a module substrate. When inserting a memory module into a socket on a main board, components of the main board may be damaged due to various reasons such as an accidental impact. As a result, the protection of components mounted on the memory module from impacts may be needed.

### SUMMARY

Embodiments of the present inventive concept include a memory device including a module substrate having a first side surface and a second side surface perpendicular to the first side surface, a semiconductor package disposed on at least one of an upper surface and a lower surface of the module substrate, a passive device disposed on at least one of the upper surface and the lower surface of the module substrate, where the passive device is electrically connected to the semiconductor package, and protective layer disposed on and covering the passive device. The module substrate may include a connector adjacent to the first side surface. The passive device may include a first passive device disposed between the connector and the semiconductor package. The protective layer may include a first protective layer covering at least a portion of the first passive device.

Embodiments of the present inventive concept provide a memory device including a module substrate having a first side surface and a second side surface perpendicular to the first side surface, an upper semiconductor package and a lower semiconductor package disposed on an upper surface and a lower surface of the module substrate, respectively, a first upper passive device disposed on the upper surface of the module substrate adjacent to the first side surface, a first upper protective layer covering at least a portion of the first upper passive device, a first lower passive device disposed on the lower surface of the module substrate, and a first lower protective layer covering at least a portion of the first lower passive device.

Embodiments of the present inventive concept provide a memory module including a module substrate having a first side surface, a second side surface perpendicular to the first side surface, and a third side surface opposite to the second side surface, an upper semiconductor package and a lower semiconductor package disposed on an upper surface and a lower surface of the module substrate, respectively, a first upper passive device disposed on the upper surface of the module substrate adjacent to the first side surface, a second upper passive device disposed on the upper surface of the module substrate adjacent to the second side surface, a third upper passive device disposed on the upper surface of the module substrate adjacent to the third side surface, a first protective layer, second protective layer, and third protective layer covering at least a portion of the first upper passive device, the second upper passive device, and the third upper passive device, respectively, a first lower passive device disposed on the lower surface of the module substrate, and a first lower protective layer covering at least a portion of the first lower passive device.

Embodiment of the present inventive concept provide a method for manufacturing a memory module including providing a module substrate having a first side surface and a second side surface perpendicular to the first side surface, disposing a semiconductor package on at least one of an upper surface and a lower surface of the module substrate, disposing a passive device on at least one of the upper surface and the lower surface of the module substrate, wherein the passive device is electrically connected to the semiconductor package, and disposing a protective layer on the passive device. In one aspect, the module substrate includes a connector adjacent to the first side surface, the passive device includes a first passive device disposed between the connector and the semiconductor package, and the protective layer includes a first protective layer covering at least a portion of the first passive device.

The method for manufacturing the memory module further includes coating a protective material on the passive device to form the protective layer, wherein the protective material has a viscosity of about 10,000 mPa·s/25° C. or more and a thixotropic index of about 1.5 or more. In some examples, a lower end of the first protective layer is spaced apart from the first side surface of the module substrate by a predetermined distance.

In some examples, the first protective layer covers an upper surface and side surfaces of the first passive device. In some examples, a long axis of the first passive device is parallel to the second side surface. In some examples, a width of the first protective layer measured along the second side surface of the module substrate is less than three times a width of the first passive device measured along the second side surface. In some examples, a distance measured from one end of the first protective layer to the first passive device is less than a width of the first passive device measured along the second side surface.

In some examples, the passive device further include a second passive device adjacent to the second side surface, and the protective layer further include a second protective layer covering the second passive device.

In some examples, the second protective layer is in contact with a side surface and a lower surface of the semiconductor package. In some examples, the second protective layer covers at least a portion of a side surface and an upper surface of the second passive device. In some examples, the module substrate further includes a slot formed by recessing the second side surface, and the second passive device is disposed between the slot and the semiconductor package.

### BRIEF DESCRIPTION OF DRAWINGS

FIG. 1 is a block diagram illustrating a memory system according to an embodiment of the present disclosure.

FIG. 2 is a plan view of a memory module according to an embodiment of the present disclosure.

FIG. 3 is a partially enlarged view of region A of the memory module illustrated in FIG. 2.

FIG. 4 is a vertical cross-sectional view of the memory module illustrated in FIG. 3, taken along line I-I′.

FIG. 5 is a partially enlarged view of region B of the memory module illustrated in FIG. 2.

FIG. 6 is a vertical cross-sectional view of the memory module illustrated in FIG. 5, taken along line II-II′.

FIGS. 7 and 8 are plan views of a memory module according to embodiments of the present disclosure.

FIG. 9 is a vertical cross-sectional view of a memory module according to an embodiment of the present disclosure.

FIGS. 10A and 10B are vertical cross-sectional views of a memory module according to an embodiment of the present disclosure.

FIGS. 11A and 11B are vertical cross-sectional views of a memory module according to an embodiment of the present disclosure.

FIG. 12 is a schematic diagram illustrating a socket of a main board.

FIGS. 13 and 14 are vertical cross-sectional views of a memory module inserted into a socket of a main board according to an embodiment of the present disclosure.

FIG. 15 is a graph illustrating an effect of a protective layer according to an embodiment of the present disclosure.

FIGS. 16 to 18 are vertical cross-sectional views of a semiconductor package according to an embodiment of the present disclosure.

### DETAILED DESCRIPTION

Hereinafter, preferred example embodiments of the present inventive concept are described with reference to the accompanying drawings as follows. The following structural or functional description is provided merely as an example and various alterations and modifications may be made to the embodiments. Here, the embodiments are not construed as limited to the disclosure and should be understood to include all changes, equivalents, and replacements within the idea and the technical scope of the disclosure.

Although terms of “first,” “second,” and the like are used to explain various components, the components are not limited to such terms. These terms are used to distinguish one component from another component. For example, a first component may be referred to as a second component, or similarly, the second component may be referred to as the first component within the scope of the present disclosure.

When it is mentioned that one component is “connected” or “accessed” to another component, it may be understood that the one component is directly connected or accessed to another component or an additional component may be interposed between the two components.

The singular forms “a”, “an”, and “the” are intended to include the plural forms as well, unless the context clearly indicates otherwise. As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms used herein including technical or scientific terms have the same meaning as commonly understood by one of ordinary skill in the art to which examples belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments are described in detail with reference to the accompanying drawings. When describing the embodiments with reference to the accompanying drawings, like reference numerals refer to like components and a repeated description related thereto may be omitted.

Electronic devices such as a memory device may include a plurality of sub components, such as a semiconductor package and a passive device. The passive device may include a resistor, an inductor, and a capacitor. In some cases, when the memory device is inserted into a main board, the passive device may be accidentally damaged and one or more passive devices may be separated from the substrate of the memory device.

Embodiments of the present inventive concept provide a memory module (or a memory device) including a protective layer and a method for manufacturing the memory module. In some embodiments, the memory module may include a plurality of semiconductor packages and a plurality of passive devices disposed on a module substrate of the memory device. In some cases, a protective layer may be disposed on at least one of the plurality of passive devices. For example, the protective layer may cover at least a portion of the passive device. In some cases, the protective layer may fully cover the passive device.

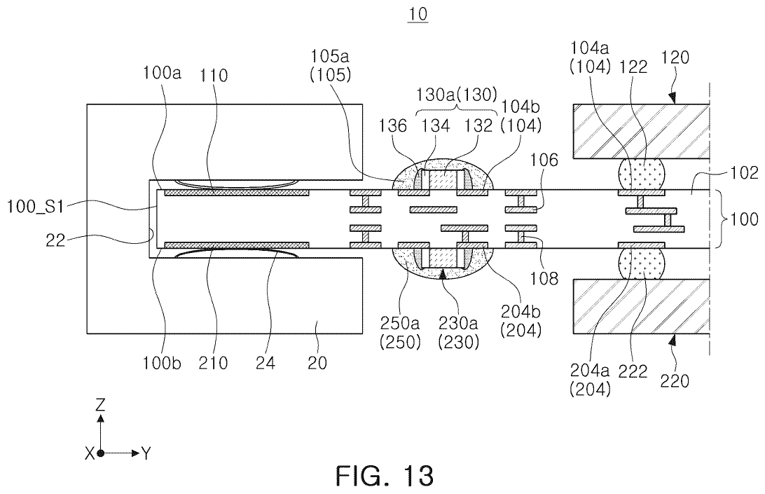

In some cases, an end of the protective layer might not exceed a predetermined distance measured from a first side surface of the module substrate. As a result, the protective layer may locally cover the passive device, ensuring compliance with the JEDEC standard and protecting the passive device from external impacts. In some embodiments, the protective layer is formed of materials having a viscosity of about 10,000 mPa·s/25° C. or more and a thixotropy index of about 1.5 or more. As a result, the protective material layer can be properly coated. Further detail on the protective material layer is described with reference to FIG. 15.

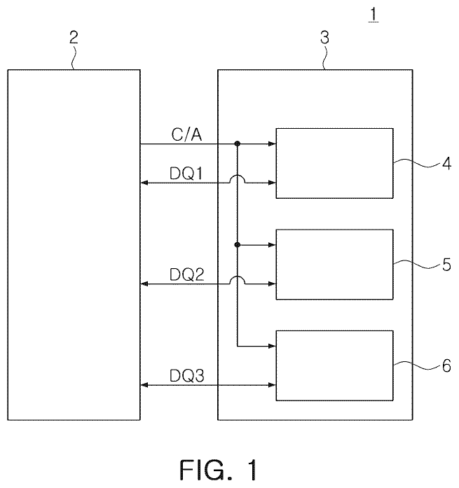

FIG. 1 is a block diagram illustrating a memory system according to an embodiment of the present disclosure. Referring to FIG. 1, a memory system 1 may include a memory controller 2 and a memory module 3. In one aspect, the memory module 3 includes a first semiconductor package 4, second semiconductor package 5, and third semiconductor package 6.

The memory controller 2 may transmit a command/address (C/A) signal (hereinafter, referred to as a “C/A signal”) to the memory module 3, and may control the memory module 3. The memory controller 2 may exchange data with the memory module based on the C/A signal (C/A). For example, the memory controller 2 may exchange data input/output signals DQ1, DQ2, and DQ3 (hereinafter, referred to as “DQ signal”).

The memory controller 2 may control the memory module 3 according to a request from a processor supporting various applications such as a server application, a personal computer (PC) application, a mobile application, and the like. The memory controller 2 may be included in a host including a processor, and may control the memory module 3 according to a request from the processor.

Transmission paths for the C/A signal C/A and the DQ signals DQ1 to DQ3 may be provided between the memory controller 2 and the memory module 3, respectively. For example, the first semiconductor package 4, second semiconductor package 5, and third semiconductor package 6 may share transmission paths for the C/A signal C/A, but may not share transmission paths for the DQ signals DQ1 to DQ3.

The memory module 3 may include first semiconductor package 4, second semiconductor package 5, and third semiconductor package 6. In some cases, the first semiconductor package 4, second semiconductor package 5, and third semiconductor package 6 may include a memory chip. The memory module 3 may represent an arbitrary device including a plurality of semiconductor packages. For example, the memory module 3 may be a memory package.

Each of the first semiconductor package 4, second semiconductor package 5, and third semiconductor package 6 may receive a C/A signal C/A from the memory controller 2, and may respectively exchange DQ signals DQ1, DQ2, and DQ3 with the memory controller 2. For example, the first semiconductor package 4 may exchange a first DQ signal DQ1 with the memory module 3 in response to the C/A signal C/A. Similarly, the second and third semiconductor packages 5 and 6 may exchange a second DQ signal DQ2 and a third DQ signal DG3 with the memory module 3, respectively. In the example shown in FIG. 1, first semiconductor package 4, second semiconductor package 5, and third semiconductor package 6 are illustrated, but the number of semiconductor packages of the memory module 3 is not limited thereto. In another example, the number of semiconductor packages included in the memory module 3 is four or more. In some examples, the number of semiconductor packages included in the memory module may be more than or equal to 1 and less than 3.

Interconnections for transmitting the C/A signal C/A to the first semiconductor package 4, second semiconductor package 5, and third semiconductor package 6 may be formed in the memory module 3. The interconnections for transmitting the C/A signal C/A to the first semiconductor package 4, second semiconductor package 5, and third semiconductor package 6 may be implemented by disposing the first and second interconnections having a linear shape in a zigzag pattern. The first semiconductor package 4, second semiconductor package 5, and third semiconductor package 6 may receive the C/A signal C/A from the memory controller 2 through first and second interconnections disposed in the zigzag pattern. Hereinafter, an interconnection structure of the first semiconductor package 4, second semiconductor package 5, and third semiconductor package 6 is described in more detail.

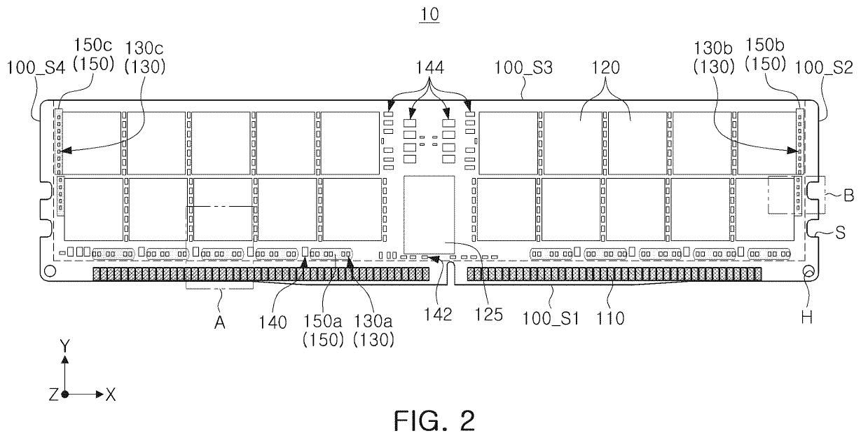

FIG. 2 is a plan view of a memory module according to an embodiment of the present disclosure. Referring to FIG. 2, a memory module 10 may include a module substrate 100, connectors 110, semiconductor packages 120, a driver chip 125, passive devices 130, and protective layers 150. The memory module 10 may correspond to the memory module 3 illustrated in FIG. 1.

The memory module 10 may be a dual in-line memory module (DIMM) complying with a joint electronic device engineering council (JEDEC) standard. For example, the memory module 10 may be a registered DIMM (RDIMM), a load reduced DIMM (LRDIMM), an unbuffered DIMM (UDIMM), a full buffered DIMM (FB-DIMM), a small outline DIMM (SO-DIMM), or another memory module (for example, a single in-line memory module).

The module substrate 100 may extend in an X-direction. For example, a width of the module substrate 100 measured in the X-direction may be greater than a width of the module substrate 100 in a Y-direction, where the Y-direction is perpendicular to the X-direction. In plan view, the module substrate 100 may have a first side surface 100_S1, a second side surface 100_S2, a third side surface 100_S3, and a fourth side surface 100_S4. The first side surface 100_S1 and the third side surface 100_S3 may be perpendicular to the Y-direction, and may be opposite to each other. The first side surface 100_S1 and the third side surface 100_S3 may be parallel with each other. The second side surface 100_S2 may intersect or meet the first side surface 100_S1. The second side surface 100_S2 and the fourth side surface 100_S4 may be perpendicular to the X-direction, and may be opposite to each other. The second side surface 100_S2 and the fourth side surface 100_S4 may be parallel to each other. In an example embodiment, the module substrate 100 may include slots S. For example, the slots S may be disposed on the second side surface 100_S2 and the fourth side surface 100_S4, and may be formed by recessing the second side surface 100_S2 and the fourth side surface 100_S4. In an example embodiment, the module substrate 100 may include holes H. For example, the holes H may be disposed between the first side surface 100_S1 and the second side surface 100_S2, and between the first side surface 100_S1 and the fourth side surface 100_S4. For example, the holes H may be disposed at the an each end of the first side surface 100_S1.

The connectors 110 may be disposed on the module substrate 100. For example, the connectors 110 may be disposed along the first side surface 100_S1 of the module substrate 100, and may be spaced apart from each other in the X-direction. Each of the connectors 110 may be electrically connected to at least one of the semiconductor packages 120, the driver chip 125, and the passive devices 130. The connectors 110 may serve as paths for the semiconductor packages 120 and the driver chip 125 to receive a DQ signal, a DQS signal, a clock signal, a command signal, and address (CK/CMD/ADD) signals from a host.

The semiconductor packages 120 may include various DRAM chips, such as a double data rate synchronous dynamic random access memory (DDR SDRAM), a DDR2 SDRAM, a DDR3 SDRAM, a DDR4 SDRAM, a DDR5 SDRAM, a low power double data rate (LPDDR) SDRAM, an LPDDR2 SDRAM, an LPDDR3 SDRAM, an LPDDR4 SDRAM, an LPDDR5 SDRAM, a graphics double data rate synchronous graphics random access memory (GDDR SGRAM), a GDDR2 SGRAM, a GDDR3 SGRAM, a GDDR4 SGRAM, a GDDR5 SGRAM, a GDDR6 SGRAM, and the like.

The semiconductor packages 120 may be memory devices in which DRAM dies, such as a high bandwidth memory (HBM), an HBM2, and an HBM3, are stacked. The semiconductor packages 120 may include at least one of an SRAM, a NAND flash memory, a NOR flash memory, an RRAM, an FRAM, a PRAM, a TRAM, and an MRAM. Types of the semiconductor packages 120 may be the same as or different from each other.

The semiconductor packages 120 and the driver chip 125 may be mounted on the module substrate 100. For example, the driver chip 125 may be disposed on a central portion of the module substrate 100 in the X-direction. The semiconductor packages 120 may be disposed on both sides of the driver chip 125.

The driver chip 125 may receive the clock signal, the command signal, and the address (CK/CMD/ADD) signals from an external device (for example, a host, a memory controller, or the like). The driver chip 125 may control the semiconductor packages 120 based on the clock signal, the command signal, and the address signals. The driver chip 125 may serve as a buffer for the clock signal, the command signal, and the address signals.

The passive devices 130 may be mounted on the module substrate 100. The passive devices 130 may include at least one of a resistor, an inductor, and a capacitor. For example, at least one of the passive devices 130 may be a resistor, and the resistors may be formed of a damping resistor array to prevent signal reflection such as overshooting/undershooting. In addition, the resistor may perform a function of current limitation, voltage drop, voltage distribution, or the like. The inductor may store energy in a magnetic field when current flows through the inductors. In some cases, inductors are used in filters, transformers, or RF circuits. The capacitor may be, for example, a multilayer ceramic capacitor (MLCC), and may perform a function of power stabilization, noise removal, filter and signal amplification, or the like. Each of the passive devices 130 may be electrically connected to at least one of the semiconductor packages 120 and the driver chip 125. At least one of the passive devices 130 may be electrically connected to a corresponding connector 110.

The passive devices 130 may be disposed adjacent to the first side surface 100_S1, the second side surface 100_S2, and the fourth side surface 100_S4 of the module substrate 100. For example, the passive devices 130 may include first passive devices 130a, second passive devices 130b, and third passive devices 130c. The first passive devices 130a may be disposed adjacent to the first side surface 100_S1, and may be spaced apart from each other in the X-direction. The second passive devices 130b may be disposed adjacent to the second side surface 100_S2, and may be spaced apart from each other in the Y-direction. The third passive devices 130c may be disposed adjacent to the fourth side surface 100_S4, and may be spaced apart from each other in the Y-direction.

The protective layers 150 may cover at least one of the passive devices 130. For example, the protective layers 150 may include first protective layers 150a, second protective layers 150b, and third protective layers 150c. The first protective layers 150a may cover the first passive devices 130a. For example, each of the first protective layers 150a may extend in the X-direction, and the first protective layers 150a may be spaced apart from each other in the X-direction. Each of the first protective layers 150a may cover at least one of the first passive devices 130a. The second protective layers 150b may cover the second passive devices 130b. For example, each of the second protective layers 150b may extend in the Y-direction, and the second protective layers 150b may be spaced apart from each other in the Y-direction. Each of the second protective layers 150b may cover at least one of the second passive devices 130b. The third protective layers 150c may cover the third passive devices 130c, and may have a structure similar to that of the second protective layers 150b. In an embodiment, the first protective layers 150a and the second protective layers 150b may entirely cover side surfaces and upper surfaces of the first passive devices 130a and the second passive devices 130b, respectively, such that the first passive devices 130a and the second passive devices 130b are not exposed.

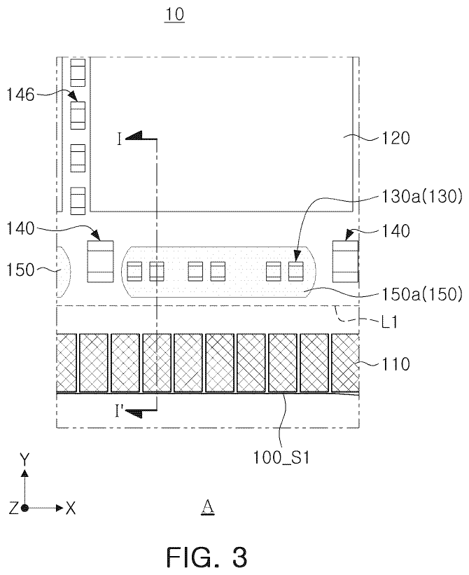

The memory module 10 may further include passive devices 140, passive devices 142, passive devices 144, and passive devices 146 (as shown in FIG. 3) mounted on the module substrate 100. The passive devices 140, the passive devices 142, the passive devices 144, and the passive devices 146 may have a structure the same as or similar to that of the passive devices 130. In some embodiments, the passive devices 140, the passive devices 142, the passive devices 144, and the passive devices 146 may have a structure different from that of the passive devices 130.

The passive devices 140 may be disposed to be adjacent to the first side surface 100_S1 of the module substrate 100, and may be disposed between the first passive devices 130a. In an embodiment, the passive devices 140 may not be covered by the protective layers 150, but the present inventive concept is not limited thereto. In some embodiments, at least a portion of the passive devices 140 may be covered by the protective layers 150. In an embodiment, at least a portion of the passive devices 140 and at least a portion of the first passive devices 130a may be covered by one protective layer 150. In an embodiment, the passive devices 140 and the first passive devices 130a may be covered by different protective layers 150.

The passive devices 142 may be disposed adjacent to the first side surface 100_S1, and may be disposed adjacent to the driver chip 125. For example, the passive devices 142 may be disposed on the central portion of the module substrate 100 in the X-direction. For example, the passive devices 142 may be disposed between the driver chip 125 and the first side surface 100_S1. In an embodiment, the passive devices 142 may not be covered by the protective layers 150, but the present inventive concept is not limited thereto.

The passive devices 144 may be disposed between the semiconductor packages 120 in the X-direction, and may be disposed adjacent to the driver chip 125. For example, the passive devices 144 may be disposed on the central portion of the module substrate 100 in the X-direction. For example, the passive devices 144 may be disposed between the driver chip 125 and the third side surface 100_S3. In an example embodiment, the passive devices 144 may not be covered by the protective layers 150, but the present inventive concept is not limited thereto.

Each of the passive devices 146 may be disposed between adjacent semiconductor packages 120 in the X-direction. For example, the passive devices 146 may be spaced apart from each other in the Y-direction, between the adjacent semiconductor packages 120 in the X-direction. In an embodiment, the passive devices 146 may not be covered by the protective layers 150, but the present inventive concept is not limited thereto.

In an embodiment, the memory module 10 may further include a temperature control chip disposed between the semiconductor packages 120. The temperature control chip may be used to measure and control temperatures of the semiconductor packages 120.

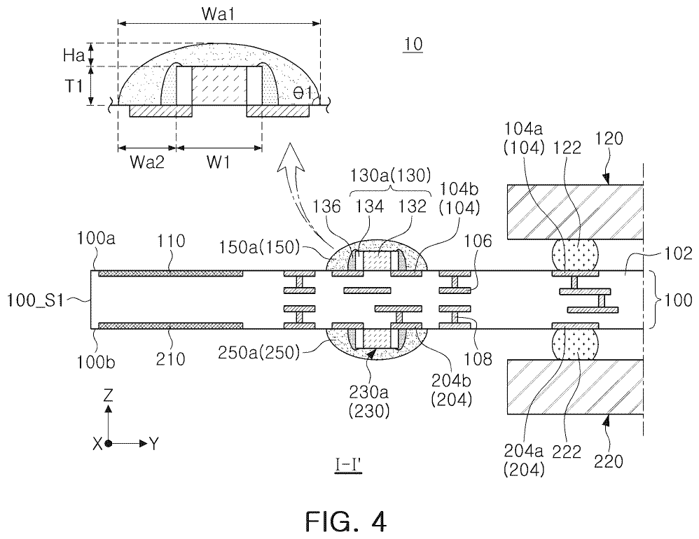

FIG. 3 is a partially enlarged view of region A of the memory module illustrated in FIG. 2. FIG. 3 may correspond to region “A” of the memory module 10 depicted in FIG. 2. FIG. 4 is a vertical cross-sectional view of the memory module illustrated in FIG. 3, taken along line I-I′.

Referring to FIGS. 3 and 4, the module substrate 100 may include an insulating layer 102, an upper interconnection layer 104, an internal interconnection 106, an internal via 108 and a connector 110. The upper interconnection layer 104, the internal interconnection 106, and the internal via 108 may be disposed in the insulating layer 102. The insulating layer 102 may be formed by stacking at least one insulating material layer. The insulating material layer may include an insulating material such as a thermosetting resin such as an epoxy resin, a thermoplastic resin such as polyimide, or a prepreg, an ABF, FR-4, or the like. In some cases, the insulating material layer may include an inorganic filler and/or a glass fiber (or glass cloth or glass fabric).

The upper interconnection layer 104 may be disposed on an upper surface 100a of the module substrate 100. An upper surface of the upper interconnection layer 104 may be exposed without being covered by the insulating layer 102. The upper interconnection layer 104 may include a first upper interconnection layer 104a electrically connected to the semiconductor package 120, and a second upper interconnection layer 104b electrically connected to the passive device 130. For example, the first upper interconnection layer 104a may be in contact with a connection bump 122, and may be electrically connected to the semiconductor package 120 through the connection bump 122.

The connector 110 may be disposed on the upper surface 100a of the module substrate 100. The connector 110 may be electrically connected to at least one of the upper interconnection layer 104, the internal interconnection 106, and the internal via 108.

The passive device 130 (e.g., a first passive device 130a) may include a body 132 and electrodes 134 disposed at both ends (or side surfaces) of the body 132. The second upper interconnection layer 104b may be in contact with the electrodes 134, and may be electrically connected to the first passive device 130a through the electrodes 134. At least one of the upper interconnection layers 104 may not be in contact with the semiconductor package 120 or the passive device 130.

The internal interconnections 106 may be disposed in the insulating layer 102, and may extend in a horizontal direction (e.g., the X-direction or the Y-direction). At least one of the internal interconnections 106 may be electrically connected to the upper interconnection layer 104. The internal vias 108 may be disposed in the insulating layer 102, and may extend in a vertical direction (e.g., the Z-direction). The internal vias 108 may connect the internal interconnections 106 to each other, or may connect the internal interconnections 160 to the upper interconnection layer 104. The upper interconnection layer 104, the internal interconnection 106, the internal via 108, and the connector 110 may include, for example, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), and alloys thereof.

As illustrated in FIG. 3, in an embodiment, the first passive device 130a may be aligned in the Y-direction. The long axis of the first passive device 130a may be parallel to the Y-direction. For example, the electrodes 134 of the first passive device 130a may be spaced apart from each other in the Y-direction with the body 132 interposed therebetween. A width of the first passive device 130a measured in the Y-direction may be greater than a width of the first passive device 130a measured in the X-direction. In some cases, the body 132 of the first passive device 130a may have a width measured in the Y-direction greater than the width of each of the electrodes 134 measured in the Y-direction.

The first passive device 130a may be bonded to the second upper interconnection layer 104b by a bonding layer 136, and may be electrically connected to the second upper interconnection layer 104b. For example, the bonding layer 136 may partially cover the electrodes 134 of the first passive device 130a and a portion of the second upper interconnection layers 104b. The bonding layer 136 may be a solder.

The first protective layer 150a may extend in the X-direction, and may cover a plurality of first passive devices 130a spaced apart from each other in the X-direction. When the connectors 110 are inserted into a socket of a main board, the first passive devices 130a may be separated from the module substrate 100 by an external impacts. However, according to embodiments of the present inventive concept, the first protective layer 150a may cover the first passive devices 130a, such that the first passive devices 130a may be protected from external impacts. A standard, such as the JEDEC, may require surface mount devices (SMD), such as the semiconductor packages 120, the driver chip 125, and the passive devices 130, to be spaced apart from the first side surface 100_S1 by a predetermined distance. For example, as illustrated in FIG. 3, the surface mount devices may be disposed farther than a first line L1 from the first side surface 100_S1 of the module substrate 100. According to embodiments of the present inventive concept, the first protective layer 150a, covering the first passive devices 130a, may also be disposed farther than the first line L1 from the first side surface 100_S1 of the module substrate 100.

For example, the first passive devices 130a and the first protective layer 150a, which covers the first passive devices 130a, may be disposed in a region between the semiconductor package 120 and the first line L1. The first protective layer 150a may not exceed the first line L1, and may be locally disposed on the module substrate 100 to cover the first passive devices 130a. For example, as illustrated in FIG. 4, a horizontal width Wa1 of the first protective layer 150a measured in the Y-direction may be less than three times a horizontal width W1 of the first passive device 130a measured in the Y-direction. For example, a distance Wa2 measured from one end of the first protective layer 150a in the Y-direction to one end of the electrodes 134 of the first passive device 130a may be less than a horizontal width W1 of the first passive device 130a measured in the Y-direction. A height Ha measured from an upper surface of the first passive device 130a to an upper end of the first protective layer 150a may be less than a thickness T1 of the first passive device 130a. An angle θ1, formed by the one end of the first protective layer 150a in the Y-direction and a lower surface of the first protective layer 150a (or the upper surface 100a of the module substrate 100), may be within a range from about 30 degrees to about 90 degrees. According to embodiments of the present inventive concept, the first protective layer 150a may locally cover the first passive devices 130a, ensuring compliance with the JEDEC standard and protecting the first passive devices 130a from external impacts.

The passive devices 140 may be disposed adjacent to the first passive devices 130a. The passive devices 140 may have a width and a height each greater than those of the first passive devices 130a, but the present inventive concept is not limited thereto. As described above, the passive devices 140 and 146 may not be covered by the protective layer 150. In some embodiments, the passive devices 140 may be in contact with the first protective layer 150a that covers the first passive devices 130a.

In an embodiment, the memory module 10 may be a DIMM. For example, as illustrated in FIG. 4, the surface mount devices may be disposed on both the upper surface 100a and the lower surface 100b of the module substrate 100. The memory module 10 may further include a semiconductor package 220, a first passive device 230a, and a first protective layer 250a, mounted on the lower surface 100b of the module substrate 100. The semiconductor package 220, the first passive device 230a, and the first protective layer 250a may have the same as or similar structures as those of the semiconductor package 120, the first passive device 130a, and the first protective layer 150a, respectively. The first passive device 230a may be disposed adjacent to the first side surface 100_S1 of the module substrate 100. It is illustrated that the first passive device 230a vertically overlaps the first passive device 130a, but the present inventive concept is not limited thereto. The first protective layer 250a may cover the first passive device 230a.

As described herein, the semiconductor package 120 and the semiconductor package 220 may be referred to as an “upper semiconductor package” and a “lower semiconductor package,” respectively. The first passive device 130a and the first passive device 230a may also be referred to as a “first upper passive device” and a “first lower passive device,” respectively. The first protective layer 150a and the first protective layer 250a may also be referred to as a “first upper protective layer” and a “first lower protective layer,” respectively.

The module substrate 100 may further include a lower interconnection layer 204 and a connector 210, disposed on the lower surface 100b of the module substrate 100. A lower surface of the lower interconnection layer 204 may be exposed without being covered by the insulating layer 102. In one aspect, the lower surface of the lower interconnection layer 204 may be substantially at the same level as the lower surface 100b. The lower interconnection layer 204 may include a first lower interconnection layer 204a electrically connected to the semiconductor package 220, and a second lower interconnection layer 204b electrically connected to the passive device 230. For example, the first lower interconnection layer 204a may be in contact with a connection bump 222, and may be electrically connected to the semiconductor package 220 through the connection bump 222.

The second lower interconnection layer 204b may be in contact with and electrically connected to the first passive device 230a. At least one of the lower interconnection layers 204 may not be in contact with the semiconductor package 220 or the passive device 230.

In some embodiments, the first protective layer 250a may be disposed to cover the passive device 230. For example, the configuration of the first protective layer 250a and the passive device 230 may be substantially similar to the configuration of the first protective layer 150a and the passive device 130. In some embodiments, a bonding layer may be disposed between the first protective layer 250a and the passive device 230. In some embodiments, the passive device 230a may also include a body and electrodes disposed adjacent to the body in the Y-direction.

The connector 210 may be disposed on the lower surface 100b of the module substrate 100. The connector 210 may be electrically connected to at least one of the semiconductor packages 220, the driver chip 125, and the passive devices 230. For example, the connector 210 may be electrically connected to at least one of the lower interconnection layer 204, the internal interconnection 106, and the internal via 108. In the present specification, the connector 110 and the connector 210 may be referred to as an “upper connector” and a “lower connector,” respectively.

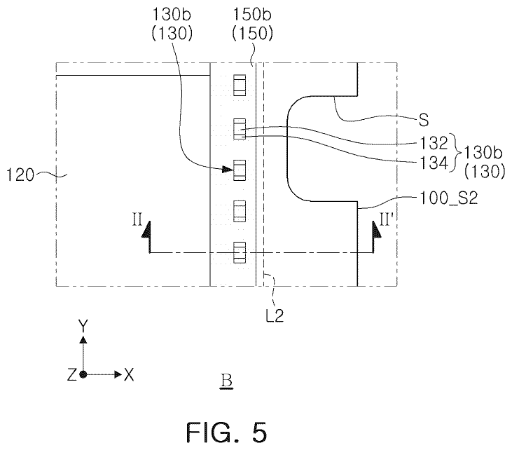

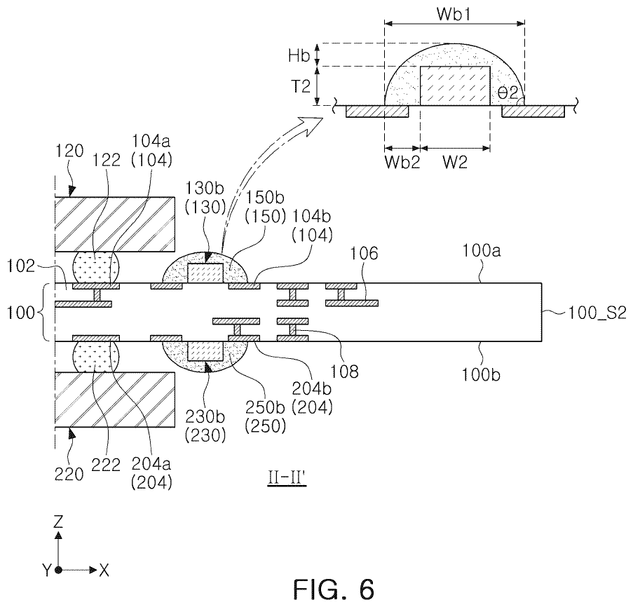

FIG. 5 is a partially enlarged view of region B of the memory module illustrated in FIG. 2. FIG. 6 is a vertical cross-sectional view of the memory module illustrated in FIG. 5, taken along line II-II′. Referring to FIGS. 5 and 6, in plan view, the second passive devices 130b may be spaced apart from each other in the Y-direction. In some embodiments, the sizes of the second passive devices 130b are different from each other. In some embodiments, the sizes of the second passive devices 130b are the same. Each of the second passive devices 130b may include a body 132 and electrodes 134 disposed on both ends of the body 132 in the Y-direction.

In an embodiment, the second passive device 130b may be aligned in the Y-direction. For example, a long axis of the second passive device 130b may be parallel to the Y-direction. For example, the electrodes 134 of the second passive device 130b may be spaced apart from each other in the Y-direction with the body 132 interposed therebetween. A width of the second passive device 130b in the Y-direction may be greater than a width of the second passive device 130b in the X-direction.

The second passive device 130b may be electrically connected to a corresponding second upper interconnection layer 104b of the module substrate 100. The second protective layer 150b may extend in the Y-direction, and may cover a plurality of second passive devices 130b, spaced apart from each other in the Y-direction. In some scenarios, when the connectors 110 are inserted into a socket of a main board, the second passive devices 130b may be damaged and separated from the module substrate 100 by external impacts. However, according to embodiments of the present inventive concept, the second protective layer 150b may cover the second passive devices 130b, such that the second passive devices 130b may be protected from external impacts. A standard, such as a JEDEC, may require surface mount devices to be spaced apart from the second side surface 100_S2 of the module substrate 100 by a predetermined distance. For example, as illustrated in FIG. 5, the surface mount devices may be required to be disposed away from a second line L2 at a direction opposite from the second side surface 100_S2 of the module substrate 100. According to some embodiments of the present inventive concept, the second protective layer 150b covering the second passive devices 130b may also be disposed at a region away from the second line L2 in the direction opposite from the second side surface 100_S2 of the module substrate 100. In an embodiment, at least a portion of the second protective layer 150b may overlap the semiconductor package 120 in a vertical direction.

The second passive devices 130b and the second protective layer 150b, which covers the second passive devices 130b, may be disposed in a region between the semiconductor package 120 and the second line L2 in the X-direction. The second protective layer 150b may not exceed the second line L2, and may be locally disposed on the module substrate 100 to cover the second passive devices 130b. For example, as illustrated in FIG. 6, a horizontal width Wb1 of the second protective layer 150b measured in the X-direction may be less than five times a horizontal width W2 of the second passive device 130b measured in the X-direction. For example, a distance Wb2 from one end of the second protective layer 150b measured in the X-direction to one nearest end of the second passive device 130b may be less than two times a horizontal width W2 of the second passive device 130b in the X-direction. A height Hb measured from an upper surface of the second passive device 130b to an upper end of the second protective layer 150b may be less than a thickness T2 of the second passive device 130b. An angle θ2, formed by the one end of the second protective layer 150b in the X-direction and a lower surface of the second protective layer 150b (or the upper surface 100a of the module substrate 100), may be within a range from about 30 degrees to about 90 degrees. According to embodiments of the present inventive concept, the second protective layer 150b may locally cover the second passive devices 130b, ensuring the compliance with a standard such as the JEDEC while protecting the second passive devices 130b from external impacts.

In an embodiment, the memory module 10 may be a DIMM. For example, as illustrated in FIG. 6, surface mount devices may be disposed on both the upper surface 100a and the lower surface 100b of the module substrate 100. The memory module 10 may further include a second passive device 230b and a second protective layer 250b, mounted on the lower surface 100b of the module substrate 100. The second passive device 230b and the second protective layer 250b may have structures respectively the same as or similar to those of the second passive device 130b and the second protective layer 150b. The second passive device 230b may be disposed to be adjacent to the second side surface 100_S2 of the module substrate 100. It is illustrated that the second passive device 230b vertically overlaps the second passive device 130b, but the present inventive concept is not limited thereto. The second protective layer 250b may cover the second passive device 230b. In an embodiment, at least a portion of the second protective layer 250b may overlap the semiconductor package 120 in a vertical direction.

According to some embodiments, the second protective layer 150b may be disposed to cover the second passive device 130b without an intervening layer. In some embodiments, a bonding layer may be disposed between the second protective layer 150b and the second passive device 130b. According to some embodiment, a portion of the semiconductor package 120 may vertically overlap with a portion of the second protective layer 150b. However, the portion of the semiconductor package 120 might not vertically overlap with the second passive device 130b. In some embodiments, the configuration of the second passive device 230b and the second protective layer 250b may be substantially the same as the configuration of the second passive device 130b and the second protective layer 150b, but disposed on the lower surface 100b of the module substrate 100.

As described herein, the second passive device 130b and the second passive device 230b may be referred to as a “second upper passive device” and a “second lower passive device,” respectively. The second protective layer 150b and the second protective layer 250b may be referred to as a “first upper protective layer” and a “first lower protective layer,” respectively.

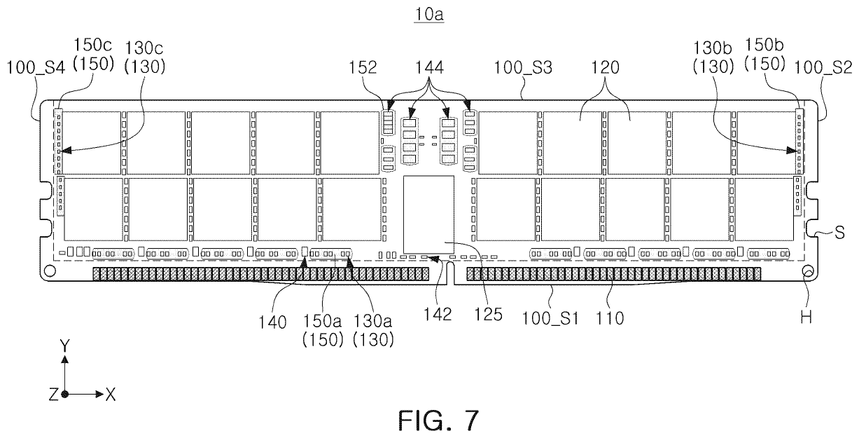

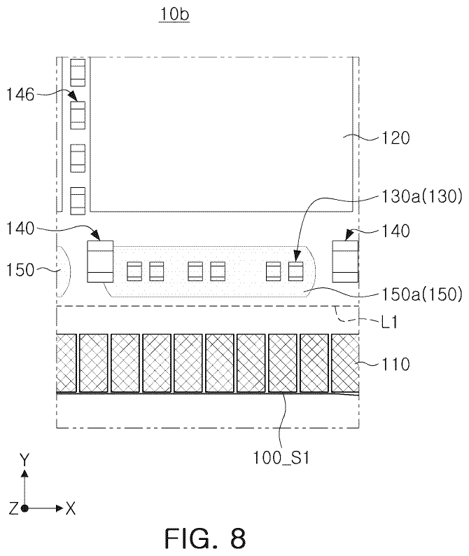

FIGS. 7 and 8 are plan views of a memory module according to embodiments of the present disclosure. Referring to FIG. 7, in an embodiment, a memory module 10a may further include protective layers 152 covering the passive devices 144. Each of the protective layers 152 may extend in the Y-direction, and may cover a plurality of passive devices 144. In some embodiments, a portion of the passive devices 144 may not be covered by the protective layers 152. In some embodiments, a group of passive devices 144 may be covered by the same protective layer 152. In some cases, each of the passive devices 144 may be covered by a different protective layer 152.

FIG. 8 are plan vies of an enlarged region of the memory module depicted in FIG. 7. Referring to FIG. 8, a memory module 10b may include a first protective layer 150a covering the first passive devices 130a. In an embodiment, at least one of the passive devices 140 may be in contact with the first protective layer 150a. For example, a side surface of at least one of the passive devices 140 may be in contact with the first protective layer 150a. In some embodiments, an upper surface of at least one of the passive devices 140 may be covered by the first protective layer 150a.

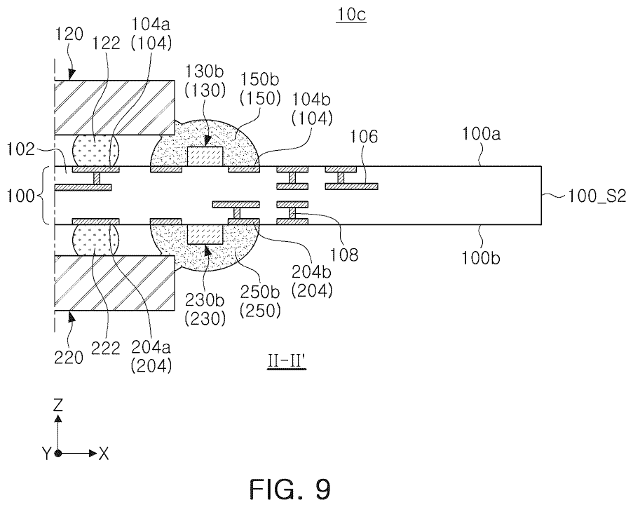

FIG. 9 is a vertical cross-sectional view of a memory module according to an embodiment of the present disclosure. Referring to FIG. 9, a memory module 10c may include a second protective layer 150b and a second protective layer 250b, respectively covering the second passive device 130b and the second passive device 230b. In an embodiment, each of the second protective layer 150b and the second protective layer 250b may be in contact with a corresponding semiconductor package 120 and the semiconductor package 220, respectively. For example, the second protective layer 150b may be in contact with at least one of a side surface and a lower surface of a corresponding semiconductor package 120. The second protective layer 250b may be in contact with at least one of a side surface and a lower surface of a corresponding semiconductor package 120. In some cases, a portion of the semiconductor package 120 might not be in contact with the second passive device 130b. Similarly, a portion of the semiconductor package 220 might not be in contact with the second passive device 230b.

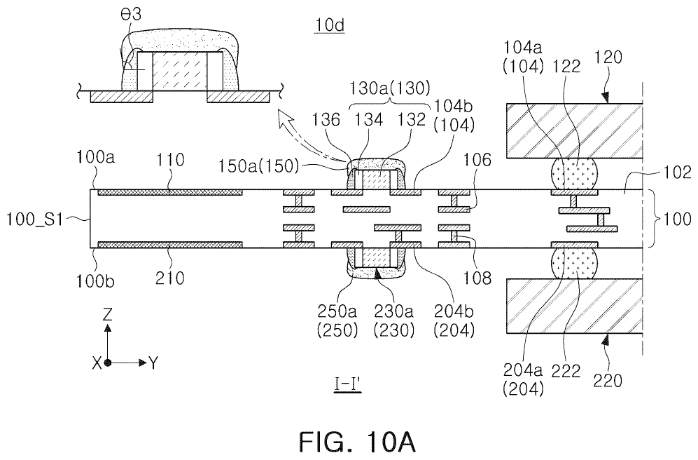

FIGS. 10A and 10B are vertical cross-sectional views of a memory module according to an embodiment of the present disclosure. FIGS. 10A and 10B may correspond to FIGS. 4 and 6, respectively.

Referring to FIG. 10A, a memory module 10d may include a first protective layer 150a and a first protective layer 250a, respectively covering the first passive device 130a and the first passive device 230a. In an embodiment, the first protective layer 150a may be spaced apart from the module substrate 100. For example, the first protective layer 150a may not be in contact with the upper surface 100a of the module substrate 100. For example, a lower end of the first protective layer 150a may be disposed on a level higher than that of the upper surface 100a of the module substrate 100, and may be in contact with a portion of the bonding layer 136. An angle θ3 at a lower end of the first protective layer 150a may be greater than about 90 degrees and less than about 150 degrees. The angle θ3 may be formed between an external surface of the first protective layer 150a and a lower surface of the first protective layer 150a parallel to the upper surface 100a of the module substrate 100. The first protective layer 250a may have a structure similar to that of the first protective layer 150a.

In some cases, the first protective layer 150a may cover the upper surface of the first passive device 130a, which includes the body 132 and the electrodes 134. The bonding layer 136 may be disposed to cover side surfaces of the electrodes 134. In some cases, the first protective layer 150a may cover and overlap a side portion of the first passive device 130a. For example, portion of the bonding layer 136 may be exposed. Similarly, the configuration of the first protective layer 250a and the first passive device 230a may be substantially the same as the configuration of the first protective layer 150a and the first passive device 130a, but disposed on the lower surface 100b of the module substrate 100.

Referring to FIG. 10B, a memory module 10e may include a second protective layer 150b and a second protective layer 250b, respectively covering the second passive device 130b and the second passive device 230b. In an embodiment, the second protective layer 150b may cover a region of the second passive device 130b. For example, a side surface of the second passive device 130b toward the second side surface 100_S2 of the module substrate 100 may be exposed without being covered by the second protective layer 150b. An upper surface of the second passive device 130b and a side surface of the second passive device 130b toward the semiconductor package 120 may be covered by the second protective layer 150b. In some cases, the semiconductor package 120 and the second protective layer 150b may be spaced apart from each other and might not be in contact with each other. Similarly, the configuration of the second protective layer 250b and the second passive device 230b may be substantially the same as the configuration of the second protective layer 150b and the second passive device 130b, but disposed on the lower surface 100b of the module substrate 100.

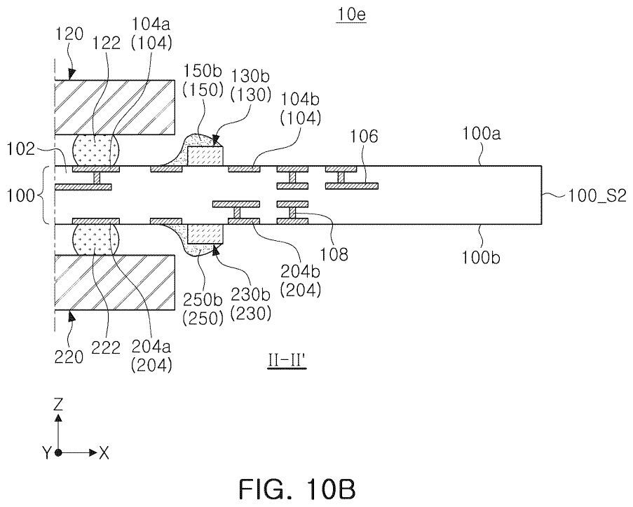

FIGS. 11A and 11B are vertical cross-sectional views of a memory module according to an embodiment of the present disclosure. FIGS. 11A and 11B may correspond to FIGS. 4 and 6, respectively.

Referring to FIGS. 11A and 11B, in an embodiment, the memory module 10 may be a single in-line memory module (SIMM). For example, surface mount devices may be disposed on the upper surface 100a of the module substrate 100, and the surface mount devices may not be disposed on the lower surface 100b of the module substrate 100. The lower interconnection layer 204 and the connector 210 are illustrated in FIGS. 11A and 11B, but the present inventive concept is not limited thereto. In an embodiment, when the memory module 10 is a SIMM, the lower interconnection layer 204 or the connector 210 may be omitted.

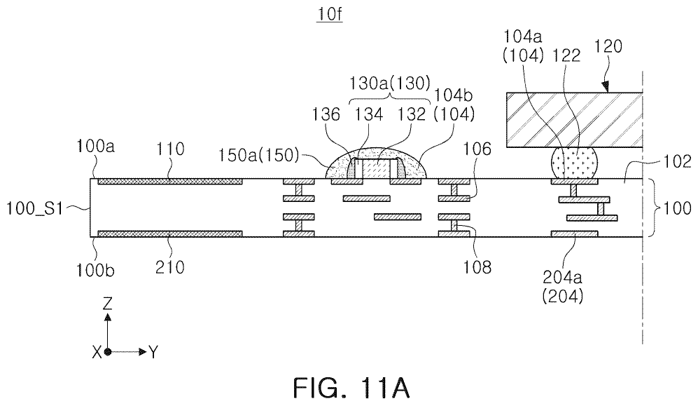

FIG. 12 is a schematic diagram illustrating a socket of a main board. Referring to FIG. 12, the memory module 10 may be inserted into an opening 22 of the socket 20. For example, the socket 20 may extend in one direction, and may include fixing members 26 at both ends thereof. The connectors 110 and 210 of the memory module 10 may be inserted into an openings of the socket 20, and a slot S of the module substrate 100 may be fastened to the fixing members 26.

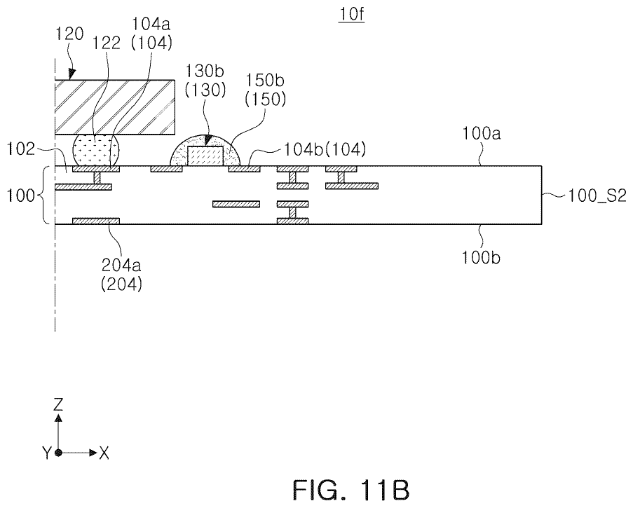

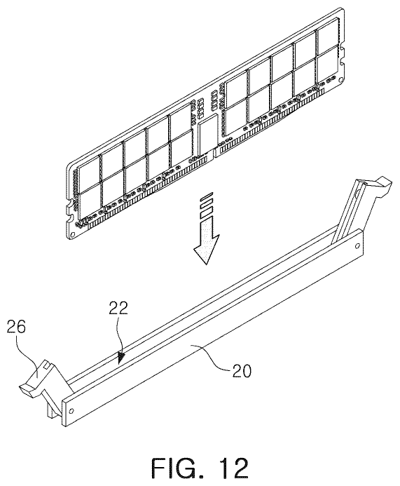

FIGS. 13 and 14 are vertical cross-sectional views of a memory module inserted into a socket of a main board according to an embodiment of the present disclosure. Referring to FIGS. 13 and 14, a portion of the module substrate 100 may be inserted into the opening 22 of the socket 20. The socket 20 may include connection terminals 24, and the connection terminals 24 may be in contact with the connectors 110 and 210. The socket 20 may be mounted on a main board, and the memory module 10 may be electrically connected to the main board through connection terminals 24 of the socket 20.

As described with reference to FIG. 3, the first passive devices 130a and the first protective layer 150a may be disposed away from the first line L1 from the first side surface 100_S1 of the module substrate 100. As described with reference to FIG. 6, the second passive devices 130b and the second protective layer 150b may be disposed away from the second line L2 from the second side surface 100_S2 of the module substrate 100. Accordingly, when the memory module 10 is inserted into the socket 20, the passive devices 130 may be prevented from being damaged and dropped by unexpected impacts. Additionally, by forming the first protective layer 150a and the second protective layer 150b away from the first line L1 and the second line L2, respectively, the memory module 10 can be inserted to the main board without a physical interference.

FIG. 15 is a graph illustrating an effect of a protective layer according to an embodiment of the present disclosure. FIG. 15 illustrates shear forces applied to passive devices in a comparative example, example 1, and example 2. Comparative example represent the data of the shear force applied to passive devices without the protective layers. Examples 1 and 2 represent the data of the shear force applied to the passive devices having protective layers. Referring to FIG. 15, in Comparative Example, when a shear force of 0.72 kgf was applied to the passive devices 130 and 230, the passive devices 130 and 230 were separated from the module substrate 100 at a predetermined rate. In Examples 1 and 2, shear forces of 3.30 kgf and 4.24 kgf were applied to the passive devices 130 and 230 having different sizes, respectively. However, the passive devices 130 and 230 were covered by protective layers 150 and 250, such that the passive devices 130 and 230 were not separated from the module substrate 100 in both Examples 1 and 2.

The protective layers 150 and 250 of the present inventive concept may be formed by disposing a protective material layer on the passive devices 130 and 230 and curing the protective material layer. Curing may include thermal curing, photo-curing, natural curing, or curing by moisture. In an embodiment, the protective layers 150 and 250 may include at least one of polyurethane acrylate, epoxy, urethane acrylate, modified acrylate, and acrylated urethane. In an embodiment, the protective layers 150 and 250 may include 25 wt % to 35 wt % of 1,6-Bis (2,3-epoxy) hexane, 5 wt % to 15 wt % of formaldehyde polymer with (chloromethyl) oxirane and phenol, 5 wt % to 15 wt % of 4,4′-(1-methylthylidene)bisphenol polymer with (chloromethyl) oxirane, and 1 wt % to 3 wt % of carbon black.

In an embodiment, the protective material layer may have high-viscosity and high-thixotropic properties. A protective material layer having high viscosity may not be excessively spread, and may be locally coated on the module substrate 100. A protective material layer having high thixotropy may refer to a high thixotropic index. A thixotropic index may refer to a rate of viscosity measured when a low shear force and a high shear force are applied, respectively. The high-thixotropic protective material layer may have relatively low viscosity during coating process, and thus may spread well, thereby improving coverage. The high-thixotropic protective material layer may have relatively high viscosity after being cured, and thus may maintain the shape thereof. According to some embodiments, the protective material layer may have high-viscosity and high-thixotropic properties, such that the protective layers 150 and 250 may be locally applied to cover the passive devices 130 and 230 while complying with the JEDEC standard. In an embodiment, the protective material layer may have a viscosity of about 10,000 mPa·s/25° C. or more. Here, the viscosity may be a value measured using a B-type viscometer under a condition of 20 rpm. In an embodiment, the protective material layer may have a thixotropy index of about 1.5 or more. Here, the thixotropy index may be a rate of a value measured using a B-type viscometer under a condition of 2 rpm and 20 rpm.

TABLE 1

| | Viscosity | Thixotropy Index |
|---|---|---|
| | (mPa · s/25° C.) | (2 rpm/20 rpm) |
| Comparative | 200 | 1.0 |
| Example 2 | | |
| Comparative | 400 | 1.0 |
| Example 3 | | |
| Example 3 | 50,000 | 4.0 |
| Example 4 | 17,000 | 1.6 |
| Example 5 | 13,000 | 5.2 |
| Comparative | 300 | 1.0 |
| Example 4 | | |
| Comparative | 40,000 | 0.9 |
| Example 5 | | |
| Comparative | 1,000 | 1.0 |
| Example 6 | | |
| Comparative | 400 | 1.0 |
| Example 7 | | |
| Comparative | 4,000 | 1.0 |
| Example 8 | | |
| Example 6 | 12,000 | 5.0 |
| Example 7 | 15,000 | 1.6 |
| Comparative | 25,000 | 1.0 |
| Example 9 | | |

Table 1 indicates various viscosities and thixotropy indices of protective material layers coated on the module substrate 100 in comparative examples and examples.

In Comparative Example 2 and Comparative Example 3, both a viscosity and a thixotropic index of a protective material layer were relative low, and the protective material layer excessively spread without being locally coated. In Examples 3 to 5, both a viscosity and a thixotropic index of a protective material layer satisfied the above-described range, and the protective material layer was properly coated. In Comparative Example 4, both a viscosity and a thixotropic index of a protective material layer were relatively low, and the protective material layer excessively spread without being locally coated. In Comparative Example 5, a thixotropic index of a protective material layer was relatively low, and the passive devices 130 and 230 were exposed without sufficiently coating the protective material layer. In Comparative Example 6 to Comparative Example 8, both a viscosity and a thixotropic index of a protective material layer were relatively low, and the protective material layer excessively spread without being locally coated. In Examples 11 and 12, both a viscosity and a thixotropic index of a protective material layer satisfied the above-described range, and the protective material layer was properly coated. In Comparative Example 9, a thixotropic index of a protective material layer was relatively low, and the protective material layer was not sufficiently coated. Referring to the results of Table 1, when a protective material layer has sufficient viscosity and low thixotropic index, the protective material layer may not sufficiently spread, and thus the passive devices 130 and 230 may be exposed. When a protective material layer has low viscosity, the protective material layer may be excessively spread without being locally coated.

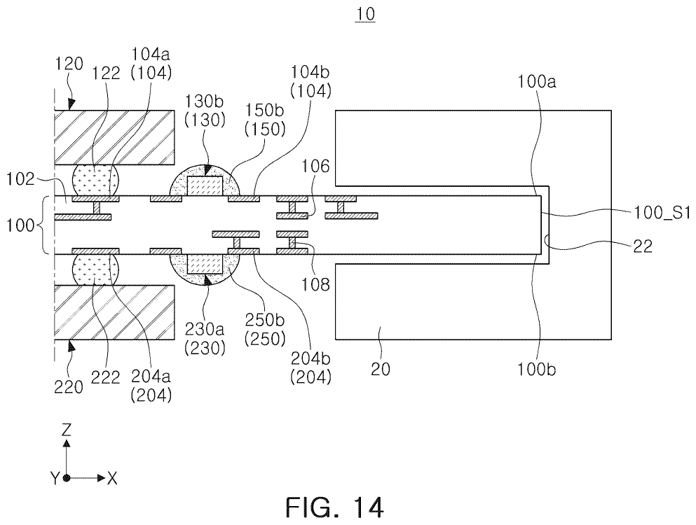

FIGS. 16 to 18 are vertical cross-sectional views of a semiconductor package according to an embodiment of the present disclosure. Referring to FIG. 16, a semiconductor package 120 may include a package substrate 1210, a chip structure CS, and a encapsulant 1230.

The package substrate 1210 may be a printed circuit board (PCB) on which the chip structure CS is mounted. The package substrate 1210 may include lower pads 1211, upper pads 1212, and a redistribution circuit 1213. The upper pads 1212 may be electrically connected to the lower pads 1211 through the redistribution circuit 1213. The lower pads 1211 may be in contact with connection bumps 122. The upper pads 1212 may be formed at a pitch, lower than that of the lower pads 1211. The redistribution circuit 1213 may include, for example, a signal pattern, a power pattern, and a ground pattern. The lower pads 1211, the upper pads 1212, and the redistribution circuit 1213 may include a conductive material, for example, at least one metal, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys thereof.

The chip structure CS may include at least one semiconductor chip 1220 disposed on an upper surface of the package substrate 1210. The semiconductor chip 1220 may be electrically connected to the upper pads 1212 of the package substrate 1210. The semiconductor chip 1220 may be a memory chip including a DRAM device, an SDRAM device, an RRAM device, a PRAM device, an MRAM device, or a spin transfer torque MRAM (STT-MRAM) device. The chip structure CS may be mounted on the package substrate 1210 in a flip chip manner. For example, a bump structure 1225, electrically connecting connection terminals 1221 of the semiconductor chip 1220 and the upper pads 1212 of the package substrate 1210 to each other, may be disposed between the chip structure CS and the package substrate 1210. The bump structure 1225 may be in the form of a ball, a pin, or a lead. For example, the bump structure 1225 may have a form in which a solder ball and a copper (Cu) pillar are coupled to each other.

The encapsulant 1230 may be disposed on the package substrate 1210, and may encapsulate at least a portion of the chip structure CS. The encapsulant 1230 may also encapsulate the semiconductor chip 1220. The encapsulant 1230 may include, for example, a thermosetting resin such as an epoxy resin, a thermoplastic resin such as polyimide, or a prepreg, an ABF, FR-4, BT, or an EMC including an inorganic filler and/or a glass fiber. An underfill member 1231, surrounding the bump structure 1225, may be disposed between the chip structure CS and the package substrate 1210. The underfill member 1231 may have a capillary underfill (CUF) structure having a boundary distinct from the encapsulant 1230. However, in some example embodiments, the underfill member 1231 may have a mole underfill (MUF) structure formed integrally with the encapsulant 1230.

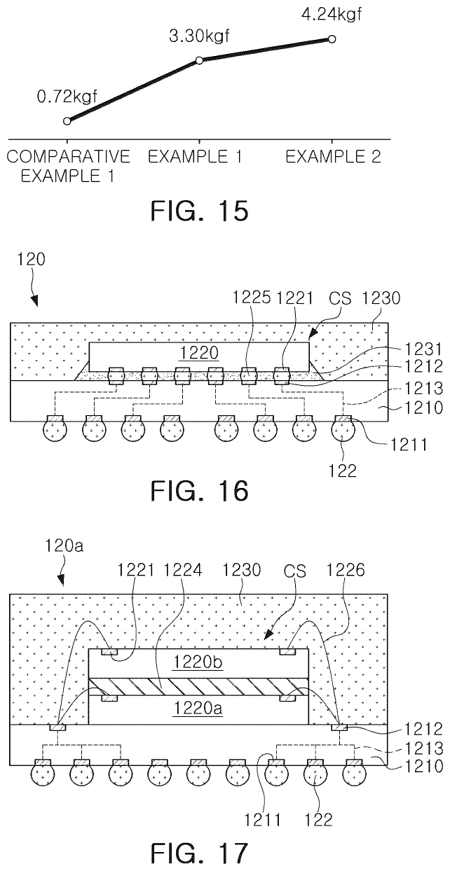

Referring to FIG. 17, in an embodiment, a semiconductor package 120a may include a chip structure CS including a plurality of semiconductor chips 1220a and 1220b mounted on a package substrate 1210 in a wire-bonding manner. The plurality of semiconductor chips 1220a and 1220b may be memory chips including a DRAM device, an SDRAM device, an RRAM device, a PRAM device, an MRAM device, or a STT-MRAM device. The number of the plurality of semiconductor chips 1220a and 1220b may be less than or greater than the number of those illustrated in the drawing. Each of the plurality of semiconductor chips 1220a and 1220b may include connection terminals 1221 electrically connected to the upper pads 1212 of the package substrate 1210 through a bonding wire 1226. The bonding wire 1226 may include gold (Au), silver (Ag), lead (Pb), aluminum (Al), copper (Cu), or alloys thereof, but the present inventive concept is not limited thereto. An adhesive member 1224 may be interposed between the plurality of semiconductor chips 1220a and 1220b. The adhesive member 1224 may include an insulating film, for example, a die attach film (DAF).

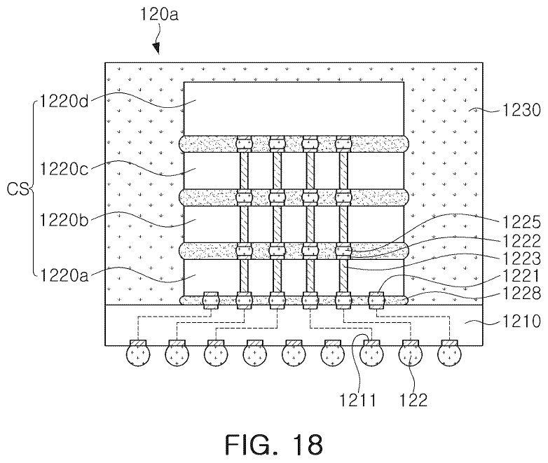

Referring to FIG. 18, a semiconductor package 120b may include a chip structure CS including a plurality of semiconductor chips 1220a, 1220b, 1220c, and 1220d electrically connected to each other through a through-electrode 1223. The plurality of semiconductor chips 1220a, 1220b, 1220c, and 1220d may include the memory chip described above. The number of the plurality of semiconductor chips 1220a, 1220b, 1220c, and 1220d may be less than or greater than the number of those illustrated in the drawing. Each of the semiconductor chips 1220a, 1220b, and 1220c, excluding an uppermost semiconductor chip 1220d, may include a through-electrode 1223 electrically connecting a lower connection terminal 1221 of one semiconductor chip with an upper connection terminal 1222 of another semiconductor chip. The through-electrode 1223 may include a metal such as tungsten (W), titanium (Ti), aluminum (Al), or copper (Cu). The through-electrode 1223 may be surrounded by a side insulating film (not illustrated). A bump structure 1225, electrically connecting the lower connection terminal 1221 and the upper connection terminal 1222 to each other. An insulating adhesive film 1228 may surround the bump structure 1225 and disposed between the plurality of semiconductor chips 1220a, 1220b, 1220c, and 1220d. The bump structure 1225 may include a solder ball and/or a copper (Cu) pillar. The insulating adhesive film 1228 may include, for example, a non-conductive film (NCF).

According to example embodiments of the present inventive concept, a protective layer may cover a passive device, thereby protecting the passive device from external impacts. The protective layer may be locally coated on a module substrate to cover the passive device while in compliance with the JEDEC standard.

While example embodiments have been shown and described above, it will be apparent to those skilled in the art that modifications and variations could be made without departing from the scope of the present inventive concept as defined by the appended claims.

What is claimed is:

1. A memory device comprising:
a module substrate having a first side surface and a second side surface perpendicular to the first side surface;
a semiconductor package disposed on at least one of an upper surface and a lower surface of the module substrate;
a passive device disposed on at least one of the upper surface and the lower surface of the module substrate, wherein the passive device is electrically connected to the semiconductor package; and
a protective layer disposed on and covering the passive device,
wherein the module substrate includes a connector adjacent to the first side surface,
wherein the passive device includes a first passive device disposed between the connector and the semiconductor package, and
wherein the protective layer includes a first protective layer covering at least a portion of the first passive device.

2. The memory device of claim 1, wherein:
the first protective layer covers an upper surface and side surfaces of the first passive device.

3. The memory device of claim 1, wherein:
a long axis of the first passive device is parallel to the second side surface.

4. The memory device of claim 3, wherein:
a width of the first protective layer measured along the second side surface of the module substrate is less than three times a width of the first passive device measured along the second side surface.

5. The memory device of claim 3, wherein:
a distance measured from one end of the first protective layer to the first passive device is less than a width of the first passive device measured along the second side surface.

6. The memory device of claim 1, wherein:
a height measured from an upper surface of the first passive device to an upper end of the first protective layer is less than a thickness of the first passive device.

7. The memory device of claim 1, wherein:
the passive device further include a second passive device adjacent to the second side surface, and
the protective layer further include a second protective layer covering the second passive device.

8. The memory device of claim 7, wherein:
the second protective layer is in contact with a side surface and a lower surface of the semiconductor package.

9. The memory device of claim 7, wherein:
the second protective layer covers at least a portion of a side surface and an upper surface of the second passive device.

10. The memory device of claim 7, wherein:
the module substrate further includes a slot formed by recessing the second side surface, and
the second passive device is disposed between the slot and the semiconductor package.

11. The memory device of claim 7, wherein:
a long axis of the second passive device is parallel to the second side surface of the module substrate.

12. The memory device of claim 11, wherein:
a width of the second protective layer measured along the first side surface is less than five times a width of the second passive device measured along the first side surface.

13. The memory device of claim 11, wherein:
a distance measured from one end of the second protective layer to the second passive device is less than two times a width of the second passive device measured along the first side surface.

14. The memory device of claim 11, wherein:
the passive device further include a third passive device disposed adjacent to the first passive device along the first side surface, and
an upper surface of the third passive device is not covered by the first protective layer.

15. The memory device of claim 14, wherein:
a side surface of the third passive device is covered by the first protective layer.

16. The memory device of claim 1, wherein:
the protective layer is formed by coating a protective material on the passive device, and
the protective material has a viscosity of about 10,000 mPa·s/25° C. or more and a thixotropic index of about 1.5 or more.

17. The memory device of claim 1, wherein:
a lower end of the first protective layer is spaced apart from the at least one of the upper surface and the lower surface of the module substrate.

18. A memory device comprising:
a module substrate having a first side surface and a second side surface perpendicular to the first side surface;
an upper semiconductor package and a lower semiconductor package disposed on an upper surface and a lower surface of the module substrate, respectively;
a first upper passive device disposed on the upper surface of the module substrate adjacent to the first side surface;
a first upper protective layer covering at least a portion of the first upper passive device;
a first lower passive device disposed on the lower surface of the module substrate; and
a first lower protective layer covering at least a portion of the first lower passive device.

19. The memory device of claim 18, wherein the module substrate further comprises:
an upper connector adjacent to the first side surface, disposed on the upper surface of the module substrate, and electrically connected to the upper semiconductor package; and
a lower connector adjacent to the first side surface, disposed on the lower surface of the module substrate, and electrically connected to the lower semiconductor package.

20. A memory device comprising:
a module substrate having a first side surface, a second side surface perpendicular to the first side surface, and a third side surface opposite to the second side surface;
an upper semiconductor package and a lower semiconductor package disposed on an upper surface and a lower surface of the module substrate, respectively;
a first upper passive device disposed on the upper surface of the module substrate adjacent to the first side surface;
a second upper passive device disposed on the upper surface of the module substrate adjacent to the second side surface;
a third upper passive device disposed on the upper surface of the module substrate adjacent to the third side surface;
a first protective layer, second protective layer, and third protective layer covering at least a portion of the first upper passive device, the second upper passive device, and the third upper passive device, respectively;
a first lower passive device disposed on the lower surface of the module substrate; and
a first lower protective layer covering at least a portion of the first lower passive device.
